(19) United States
(12) Patent Application Publication
(10) Pub. No.: US 2026/0066871 A1
(43) Pub. Date: Mar. 5, 2026

(54) Surface Acoustic Wave Device for Reducing Noise

(71) Applicant: RichWave Technology Corp., Taipei City (TW)

(72) Inventors: Shih-Meng Lin, Taipei City (TW); Shih-Che Chen, Taipei City (TW)

(73) Assignee: RichWave Technology Corp., Taipei City (TW)

(21) Appl. No.: 18/950,179

(22) Filed: Nov. 18, 2024

(30) Foreign Application Priority Data
Sep. 2, 2024 (TW) 113133106

(51) Int. Cl. H03H 9/02; H03H 3/08; H03H 9/25

(52) U.S. Cl. CPC H03H 9/02818; H03H 3/08; H03H 9/25

(57) ABSTRACT

An acoustic wave device includes a piezoelectric substrate and a series-coupled transducer set. The piezoelectric substrate has a first surface. The series-coupled transducer set includes a first transducer and a second transducer coupled in series, and disposed on the first surface of the piezoelectric substrate. The first transducer includes a first electrode and a common electrode. The second transducer includes a second electrode and the common electrode. The common electrode is floating, and the first transducer and the second transducer are coupled in series through the common electrode.

### TECHNICAL FIELD

The present invention relates to an acoustic wave device, and in particular to a surface acoustic wave device for reducing noise.

### BACKGROUND

Surface acoustic wave (SAW) devices can be used for conversion and transmission of electrical signals and acoustic signals. SAW devices have many applications. For example, SAW filters are used to filter out noise and retain wireless signals in specific frequency bands. SAW filters have the characteristics of low transmission loss, good anti-electromagnetic interference performance, and small size, so they are widely used in various communication products. However, existing SAW filters will produce energy leakage, resulting in a decrease in quality factor. In addition, SAW devices can also be used as resonators.

### SUMMARY

An embodiment provides an acoustic wave device. The acoustic wave device includes a piezoelectric substrate and a series-coupled transducer set. The piezoelectric substrate has a first surface. The series-coupled transducer set includes a first transducer and a second transducer coupled in series, and disposed on the first surface of the piezoelectric substrate. The first transducer includes a first electrode and a common electrode. The second transducer includes a second electrode and the common electrode. The common electrode is floating. The first transducer and the second transducer are coupled in series through the common electrode.

Another embodiment provides a method of manufacturing an acoustic wave device. The method includes providing a piezoelectric substrate with a first surface, forming a conductive layer on the first surface, and patterning the conductive layer to form a patterned conductive layer. The patterned conductive layer includes a first transducer and a second transducer. The first transducer includes a first electrode and a common electrode. The second transducer includes a second electrode and the common electrode. The common electrode is floating. The first transducer and the second transducer are coupled in series through the common electrode.

### BRIEF DESCRIPTION OF THE DRAWINGS

FIG. 1 is a top view of an acoustic wave device according to an embodiment of the present invention.

FIG. 2 is a top view of an acoustic wave device according to another embodiment of the present invention.

FIG. 3 is a top view of an acoustic wave device according to another embodiment of the present invention.

FIG. 4 is a top view of an acoustic wave device according to another embodiment of the present invention.

FIG. 5 is a top view of an acoustic wave device according to another embodiment of the present invention.

FIG. 6 is a flow chart of a manufacturing method of an acoustic wave device according to an embodiment of the present invention.

### DETAILED DESCRIPTION

Below, exemplary embodiments will be described in detail with reference to accompanying drawings so as to be easily realized by a person having ordinary knowledge in the art. The inventive concept may be embodied in various forms without being limited to the exemplary embodiments set forth herein. Descriptions of well-known parts are omitted for clarity, and like reference numerals refer to like elements throughout.

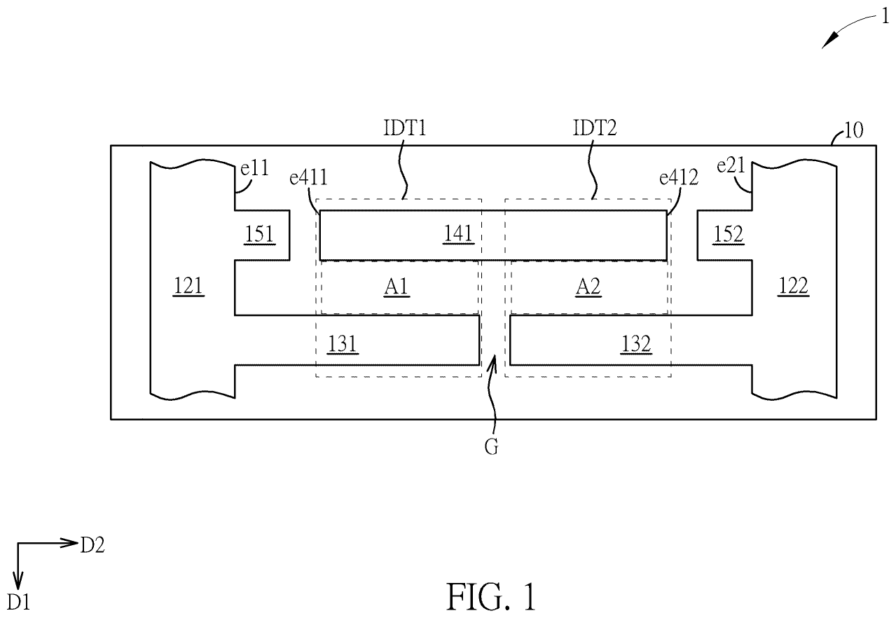

FIG. 1 is a top view of an acoustic wave device 1 according to an embodiment of the present invention. In some embodiments, the acoustic wave device 1 may be a surface acoustic wave (SAW) filter. For example, the acoustic wave device 1 can convert a radio frequency signal from an antenna into an acoustic wave, process the acoustic wave to generate a filtered signal, and output the filtered signal. Radio frequency signals and filtered signals are electrical signals. This is only an example of the use of the acoustic wave device 1, but the present invention is not limited thereto. In other embodiments, the acoustic wave device 1 can also be used for other purposes.

In some embodiments, the acoustic wave device 1 may include a piezoelectric substrate 10 and a series-coupled transducer set disposed on the surface of the piezoelectric substrate 10. The transducer set may include a plurality of interdigital transducers (IDTs). In this embodiment, the transducer set may include a first transducer IDT1 and a second transducer IDT2, but the invention is not limited thereto. In some embodiments, a transducer set may include a positive even integer of sets of transducers. The piezoelectric substrate 10 may include a substrate and a piezoelectric material layer disposed on the substrate. For example, the substrate of the piezoelectric substrate 10 may include a silicon substrate. The piezoelectric material layer may include piezoelectric single crystals, piezoelectric polycrystals (piezoelectric ceramics), piezoelectric polymers, and/or piezoelectric composite materials. For example, the piezoelectric material layer may include zinc oxide (ZnO), aluminum nitride (AlN), and/or lithium tantalate (LiTaO3). The transducer set may include metal materials, and the metal materials may include any combination of molybdenum (Mo), copper (Cu), aluminum (Al), gold (Au), platinum (Pt), and tungsten (W).

In some embodiments, the series-coupled transducer set may be disposed on the first surface of the piezoelectric substrate 10 and may include a bar 121, electrodes 131 and 132, a common electrode 141, and a bar 122. As shown in FIG. 1, the bar 121 may extend along the axis D1, and the bar 122 may extend along the axis D1. In some embodiments, the bar 121 has a side e11 parallel to the axis D1, and the bar 122 has a side e21 parallel to the axis D1. The electrode 131 may contact the side e11 of the bar 121, and extend from the side e11 of the bar 121 along the axis D2. The electrode 132 may contact the side e21 of the bar 122, and extend from the side e21 of the bar 122 along the axis D2. The electrode 131 and the electrode 132 can be aligned along the axis D2, forming a straight line. The electrode 131 and the electrode 132 do not contact each other and have a gap G along the axis D2. The common electrode 141 is floating. The common electrode 141 has a first end e411 and a second end e412. The distance between the first end e411 of the common electrode 141 and the side e11 of the bar 121 and the distance between the second end e412 of the common electrode 141 and the side e21 of the bar 122 may be the same.

The transducer IDT1 may include an electrode 131 and a common electrode 141, and the transducer IDT2 may include an electrode 132 and the common electrode 141, so that the transducer IDT1 and the transducer IDT2 are series-coupled through the common electrode 141. The electrode 131 and the common electrode 141 may have an overlapped area A1 along the projection of the axis D1, and the electrode 132 and the common electrode 141 may have an overlapped area A2 along the projection of the axis D1. Acoustic waves can propagate in the overlapped areas A1 and A2. In one embodiment, the overlapped area A1 and the overlapped area A2 have the same length along the axis D2. The common electrode 141 is spaced apart from the electrodes 131 and 132 in the axis D1. The electrodes 131, 132, and the common electrode 141 may be parallel to the axis D2, and the bar 121 may be parallel to the bar 122. In the above embodiment, the axis D2 may be perpendicular to the axis D1, and both the axis D1 and the axis D2 are parallel to the first surface of the piezoelectric substrate 10. In one embodiment, the axis D2 and the axis D1 may form an acute angle.

The series-coupled transducer set may further include a dummy electrode 151 and a dummy electrode 152. The dummy electrode 151 extends from the side e11 along the axis D2, and the dummy electrode 152 extends from the side e21 along the axis D2. The dummy electrode 151 and the dummy electrode 152 are aligned with the common electrode 141 along the axis D2 to form a straight line. The dummy electrode 151, the dummy electrode 152 and the common electrode 141 are separated from each other. By providing the dummy electrode 151 and the dummy electrode 152, the leakage of the acoustic signal along the axis D2 can be further reduced, thereby improving the quality factor of the acoustic wave device 1. The bar 121, the electrodes 131 and 132, the common electrode 141, the bar 122, the dummy electrode 151, and the dummy electrode 152 may be made of the same or different metal materials.

In summary, the input electrical signal is inputted from the bar 121, enters the electrode 131, is converted into an acoustic wave signal in the overlapped area A1, and is transmitted to the common electrode 141. Then, the common electrode 141 converts the electrical signal into an acoustic wave signal in the overlapped area A2 and transmits it to the electrode 132. The electrode 132 finally transmits the electrical signal to the bar 122 to complete the filtering and transmission of the signal. During the propagation of acoustic waves, some undesirable phenomena will occur. When the acoustic wave propagates from the electrode 131 to the common electrode 141 in the transducer IDT1, clutter in various directions may be generated. Similarly, when the acoustic wave propagates from the common electrode 141 to the electrode 132 in the transducer IDT2, corresponding clutter will also be generated. However, due to the symmetrical structure of the series-coupled transducer set, the clutter interference of the transducer IDT1 and the transducer IDT2 can be effectively eliminated, which is better than using only one single transducer. The acoustic wave device 1 effectively improves the quality of acoustic wave transmission and reduces clutter interference by leveraging the series structure and symmetry of the transducer IDT1 and the transducer IDT2, thereby enhancing overall performance.

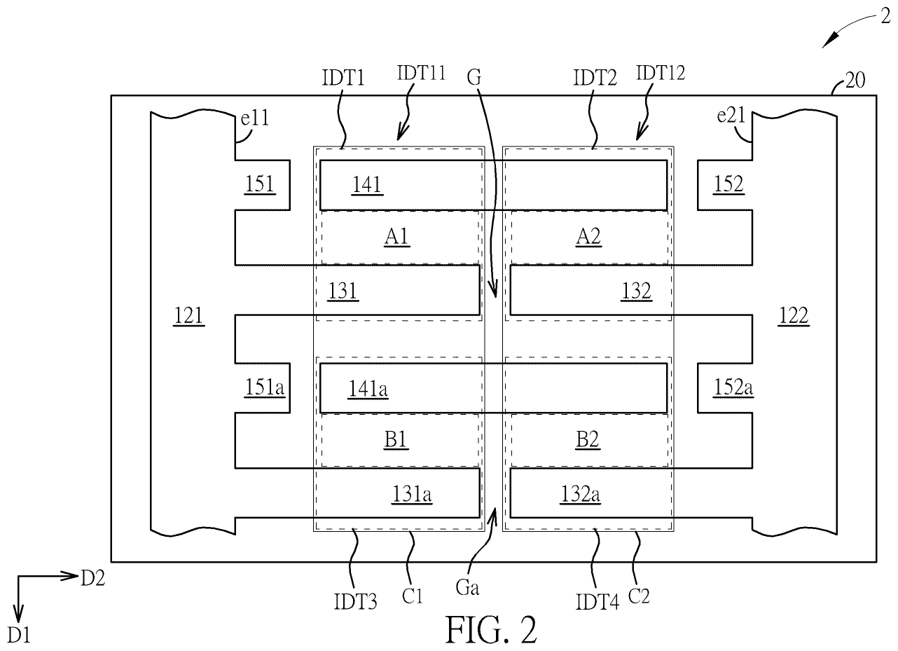

FIG. 2 is a top view of an acoustic wave device 2 according to another embodiment of the present invention. In some embodiments, the acoustic wave device 2 may be a surface acoustic wave (SAW) filter. For example, the acoustic wave device 2 can convert a radio frequency signal from an antenna into an acoustic wave, process the acoustic wave to generate a filtered signal, and output the filtered signal. Radio frequency signals and filtered signals are electrical signals. The purpose of the acoustic wave device 2 is only illustrated here, but the present invention is not limited thereto. In other embodiments, the acoustic wave device 2 can also be used for other purposes.

In some embodiments, the acoustic wave device 2 may include a piezoelectric substrate 20 and a transducer set disposed on the surface of the piezoelectric substrate 20. The transducer set may include a plurality of interdigital transducers (IDTs). In this embodiment, the transducer set may include a transducer IDT1, a transducer IDT2, a transducer IDT3, and a transducer IDT4, but the invention is not limited thereto. In some embodiments, a transducer set may include any dual array of transducers. The piezoelectric substrate 20 may include a substrate and a piezoelectric material layer disposed on the substrate. For example, the substrate of the piezoelectric substrate 20 may include a silicon substrate. The piezoelectric material layer may include piezoelectric single crystals, piezoelectric polycrystals (piezoelectric ceramics), piezoelectric polymers, and/or piezoelectric composite materials. For example, the piezoelectric material layer may include zinc oxide (ZnO), aluminum nitride (AlN), and/or lithium tantalate (LiTaO3). The transducer may include metal materials, and the metal materials may include any combination of molybdenum (Mo), copper (Cu), aluminum (Al), gold (Au), platinum (Pt), and tungsten (W).

In some embodiments, the transducer set may be disposed on the first surface of the piezoelectric substrate 20 and may include a bar 121, electrodes 131, 132, 131a and 132a, common electrodes 141 and 141a and the bar 122. As shown in FIG. 2, the bar 121 may extend along the axis D1, and the bar 122 may extend along the axis D1. In some embodiments, the bar 121 has a side e11 parallel to the axis D1, and the bar 122 has a side e21 parallel to the axis D1. The electrode 131 may contact the side e11 of the bar 121 and extend from the side e11 of the bar 121 along the axis D2. The electrode 132 may contact the side e21 of the bar 122 and extend from the side e21 of the bar 122 along the axis D2. The first electrode 131 and the electrode 132 may be aligned along the axis D2. The electrode 131 and the electrode 132 do not contact each other and have a gap G along the axis D2. The electrode 131a may contact the side e11 of the bar 121 and extend from the side e11 of the bar 121 in the axis D2. The electrode 132a can contact the side e21 of the bar 122 and extend from the side e21 of the bar 122 along the axis D2. The first electrode 131a and the second electrode 132a can be aligned along the axis D2. The electrode 131a and the electrode 132a do not contact each other and have a gap Ga along the axis D2.

The two common electrodes 141 and 141a are floating, the common electrode 141 and the electrode 131 form an overlapped area A1, and the common electrode 141 and the electrode 132 form an overlapped area A2. Acoustic waves can propagate in overlapped areas A1 and A2. According to the foregoing description, the transducer IDT1 and the transducer IDT2 may be coupled in series via the common electrode 141. The common electrode 141a and the electrode 131a form an overlapped area B1, and the common electrode 141a and the electrode 132a form an overlapped area B2. Acoustic waves can propagate in the overlapped areas B1 and B2. The electrode 131a and the common electrode 141a form the transducer IDT3, and the electrode 132a and the common electrode 141a form the transducer IDT4, so that the transducer IDT3 and the transducer IDT4 are coupled in series through the common electrode 141a. In one embodiment, the common electrode 141 is not coupled to the common electrode 141a, and the same geometric structure of the common electrode 141 is the same as the same geometric structure of the common electrode 141a, so that the potential of the common electrode 141 is the same as the potential of the common electrode 141a. In one embodiment, the overlapped area A1 formed by the electrode 131 and the common electrode 141 has the same length as the overlapped area A2 formed by the electrode 132 and the common electrode 141 along the axis D1. For example, the length of the overlapped area A1 and the overlapped area A2 is along a length on the axis D1, and the overlapped area B1 formed by the electrode 131a and the common electrode 141a has the same length as the overlapped area B2 formed by the electrode 132a and the common electrode 141a. The common electrode 141 is separated from the electrodes 131 and 132 in the axis D1, and the common electrode 141a is separated from the electrodes 131a and 132a in the axis D1. The electrodes 131, 132, and the common electrode 141 may be parallel to the axis D2, and the bar 121 may be parallel to the bar 122. The electrodes 131a, 132a, 141a may be parallel to the axis D2. In the above embodiment, the axis D2 may be perpendicular to the axis D1, and both the axis D1 and the axis D2 are parallel to the first surface of the piezoelectric substrate 10. In another embodiment, the axis D2 and the axis D1 may form an acute angle.

In an embodiment, a transducer may include a plurality of electrodes and a plurality of common electrodes. In some embodiments, common electrodes and electrodes can be added arbitrarily parallel to the electrodes 131, 131a, 132, and 132a to form a series-coupled transducer set. The two series-coupled transducer sets shown in FIG. 2 are only illustrated as an example, the present invention is not limited thereto, and N sets of transducers can be coupled in parallel. N is a positive integer. For example, in FIG. 2, the transducer IDT1 and the transducer IDT3 aligned along the axis D1 may include two electrodes 131, 131a and two common electrodes 141, 141a to form a transducer IDT11. Under the same electrical structure, there will still be acoustic waves transmitted between the electrode 131 and the common electrode 141a and converted into electrical signals, so the electrodes 131, 131a and the two common electrodes 141, 141a of the transducer IDT11 can project along axis D1 to have an overlapped area C1. Furthermore, the electrodes 132, 132a and the two common electrodes 141, 141a form the transducer IDT12, and the electrodes 132, 132a and the two common electrodes 141, 141a of the transducer IDT12 may have an overlapped area C2 along the projection of the axis D1. The transducers IDT11 and IDT12 are coupled in series with each other.

In some embodiments, the series-coupled transducer set may include a dummy electrode 151a and a dummy electrode 152a. The dummy electrode 151a extends from the side e11 along the axis D2, and the dummy electrode 152a extends from the side e21 along the axis D2. The dummy electrode 151a and the dummy electrode 152a are aligned with the common electrode 141a along the axis D2 to form a straight line. The dummy electrode 151a, the dummy electrode 152a and the common electrode 141a are spaced apart. By providing the dummy electrode 151a and the dummy electrode 152a, the leakage of the acoustic signal along the axis D2 can be further reduced, thereby improving the quality factor of the acoustic wave device 2. The bar 121, the electrodes 131, 132, 131a and 132a, the common electrodes 141 and 141a, the bar 122 and the dummy electrode 151, the dummy electrode 151a, the second dummy electrode 152 and the dummy electrode 152a can be formed by the same or different metal materials.

In summary, the input electrical signal is inputted from the bar 121, enters the electrodes 131, 131a, is converted into an acoustic wave signal in the overlapped areas A1, B1, and is transmitted to the common electrodes 141, 141a. Then, the common electrodes 141 and 141a convert the electrical signals into acoustic wave signals in the overlapped areas A2 and B2, and transmit them to the electrodes 132 and 132a. The electrodes 132 and 132a finally transmit the electrical signal to the bar 122 to complete the filtering and transmission of the signal.

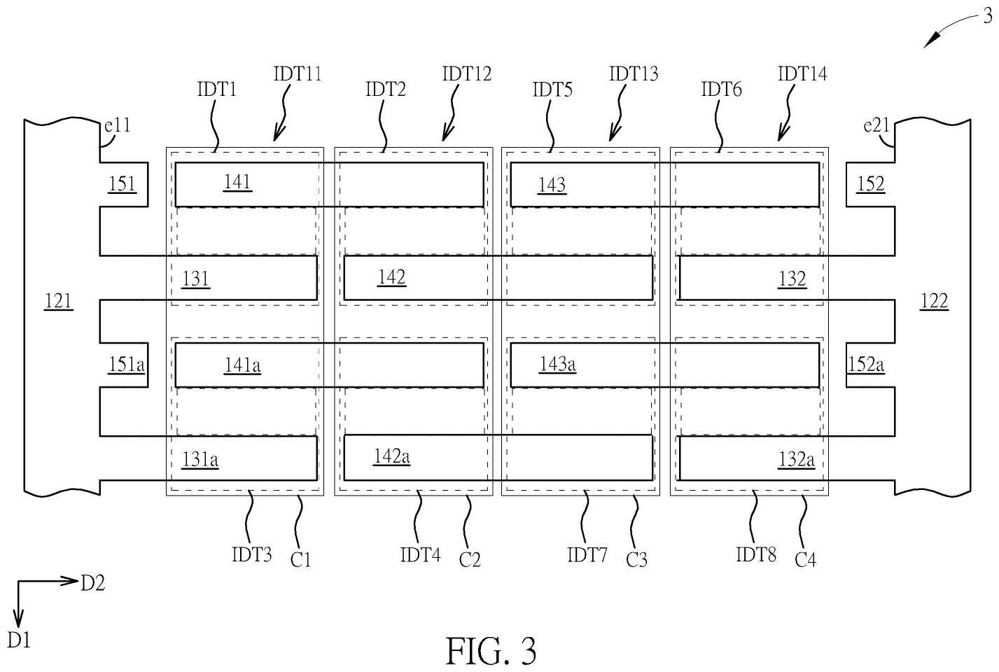

FIG. 3 is a top view of an acoustic wave device 3 according to another embodiment of the present invention. The number of acoustic wave transducers in the acoustic wave device 3 can be a positive even integer. In FIG. 3, transducers IDT1, IDT2, IDT5, and IDT6 form a series transducer set, and transducers IDT3, IDT4, IDT7, and IDT8 also form a series transducer set. The number of the transducers in the series transducer set can be a positive even integer, such as 6, 8 . . . etc., and is not limited to 4 in FIG. 3. The dummy electrode 151 and the dummy electrode 152 are aligned with the plurality of common electrodes 141 and 143 along the axis D2 to form a straight line. The electrodes 131 and 132 are aligned with one or more common electrodes 142 along the axis D2 to form a straight line. The dummy electrode 151a and the dummy electrode 152a are aligned with the plurality of common electrodes 141a and 143a along the axis D2 to form a straight line. The electrodes 131a, 132a are aligned with the one or more common electrodes 142a along the axis D2 to form a straight line. The transducers IDT1, IDT2, IDT3, IDT4, IDT5, IDT6, IDT7, and IDT8 formed by this architecture are shown in the dotted line in FIG. 3, which can effectively filter and reduce the convex wave effect in the frequency response.

The transducer shown in FIG. 3 may include a plurality of electrodes and a plurality of common electrodes. In one embodiment, the transducer IDT1 and the transducer IDT3 are aligned along the axis D1 to form the transducer IDT11. Under the same electrical structure, acoustic waves are transmitted and converted into electrical signals between the electrode 131 and the common electrode 141a. The transducer IDT2 and the transducer IDT4 are aligned along the axis D1 to form the transducer IDT12. The transducer IDT5 and the transducer IDT7 are aligned along the axis D1 to form the transducer IDT13. The transducer IDT6 and the transducer IDT8 are aligned along the axis D1 to form the transducer IDT14. Moreover, the electrodes 131, 131a and the two common electrodes 141, 141a of the transducer IDT11 can have an overlapped area C1 along the projection of the axis D1, and the common electrodes 141, 141a, 142, 142a of the transducer IDT12 can have an overlapped area C2 along the projection of the axis D1. The common electrodes 143, 143a, 142, 142a of the transducer IDT13 can have an overlapped area C3 along the projection in the axis D1. The electrodes 132, 132a and the two common electrodes 143, 143a of the transducer IDT14 can have an overlapped area C4 along the projection of the axis D1. The transducers IDT11, IDT12, IDT13 and IDT14 are sequentially coupled in series.

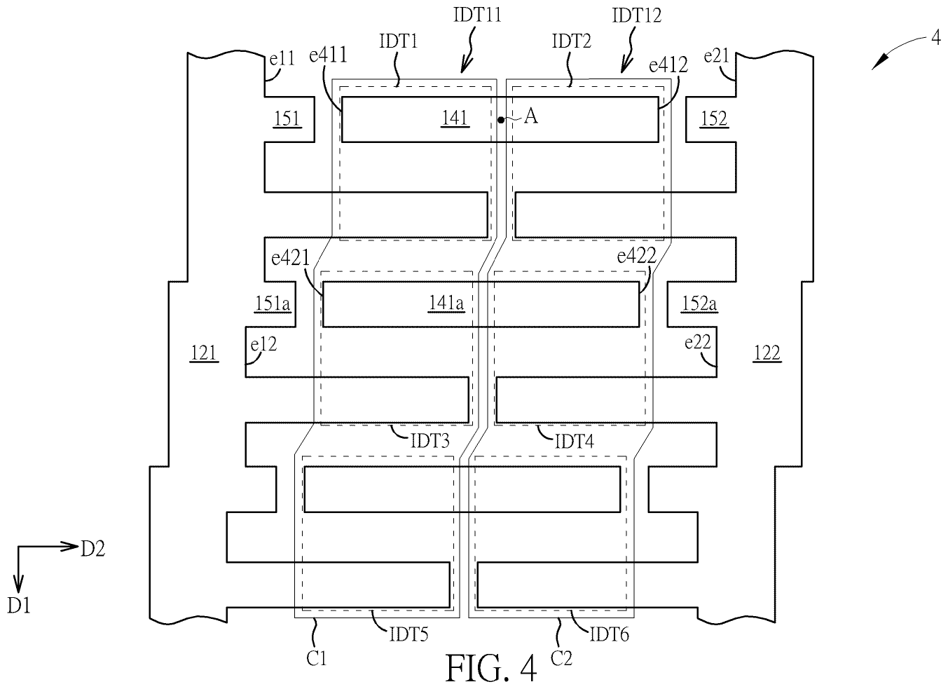

FIG. 4 is a top view of an acoustic wave device 4 according to another embodiment of the present invention. The bar 121 has a side e11 and a side e12, and both the side e11 and the side e12 extend along the axis D1. The bar 122 has a side e21 and a side e22, and both the side e21 and the side e22 extend along the axis D1. The common electrode 141a has a first end e421 and a second end e422. The distance between the first end e421 of the common electrode 141a and the side e12 of the bar 121 and the distance between the second end e422 of the common electrode 141a and the side e22 of the bar 122 may be the same. However, in some embodiments, the extension of the side e11 and the extension of the side e12 may not be co-linear, and the extension of the side e21 and the extension of the side e22 may not be co-linear. The distance between the first end e411 of the common electrode 141 and the side e12 of the bar 121 is greater than the distance between the first end e421 of the common electrode 141a and the side e11 of the bar 121. The extension of the bar 121 is not parallel to the axis D1. The distance between the second end e412 of the common electrode 141 and the side e22 of the bar 122 is smaller than the distance between the second end e422 of the common electrode 141 a and the side e21 of the bar 122. The extension of the bar 122 is not parallel to the axis D1. The series-coupled transducer set may further include a dummy electrode 151a and a dummy electrode 152a. The dummy electrode 151a contacts the side e12 of the bar 121 and extends from the side e12 of the bar 121 along the axis D2. The dummy electrode 152a contacts the side e22 of the bar 122 and extends from the side e22 of the bar 122 along the axis D2. The dummy electrode 151a, the common electrode 141a and the dummy electrode 152a are aligned along the axis D2. Along the axis D2, the lengths of the dummy electrode 151, the dummy electrode 152, the dummy electrode 151a and the dummy electrode 152a may be the same. In some embodiments, the distance between the center A of the common electrode 141 and the side e12 of the bar 121 is not equal to the distance between the center A of the common electrode 141 and the side e11 of the bar 121. For transducers IDT5 and IDT6, reference can be made to the above contents, and details will not be described again here.

The transducer shown in FIG. 4 may include a plurality of electrodes and a plurality of common electrodes. In one embodiment, the transducer IDT1, the transducer IDT3, and the transducer IDT5 are aligned parallel to the bar 121 to form the transducer IDT11. Under the similar electrical structure, the transducer IDT2, the transducer IDT4 and the transducer IDT6 are aligned parallel to the bar 121 to form the transducer IDT12, and the transducers IDT11 and IDT12 are coupled in series. The number of transducers can be a positive even integer, for example but not limited to 6, 8 . . . , etc. The transducers are coupled in series. The transducers IDT1, IDT2, IDT3, IDT4, IDT5, and IDT6 formed by this architecture are shown in the dotted line in FIG. 4, which can effectively filter and reduce the convex wave effect in the frequency response.

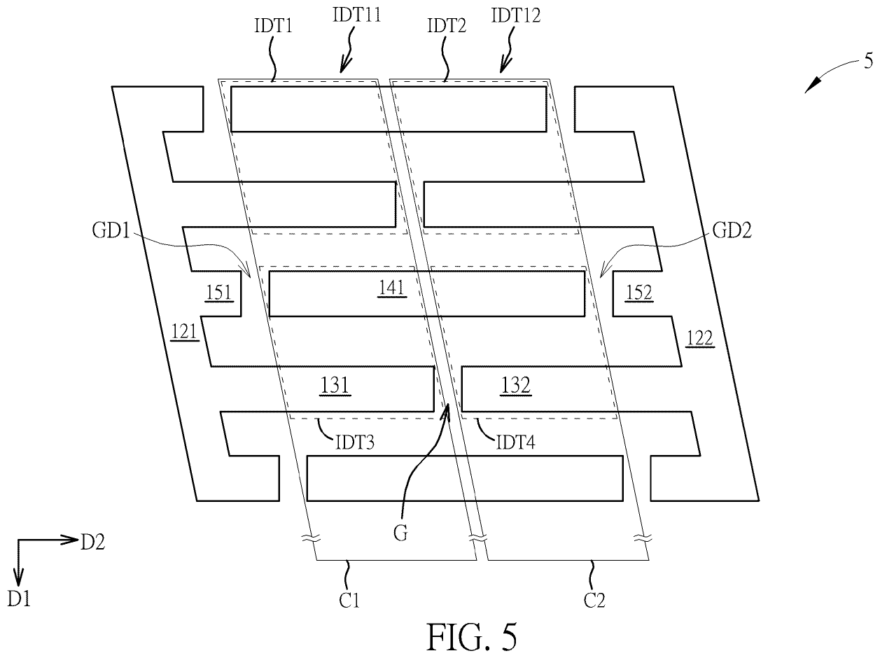

FIG. 5 is a top view of an acoustic wave device 5 according to another embodiment of the present invention. A first gap GD1 is formed between the dummy electrode 151 and the common electrode 141, and a second gap GD2 is formed between the dummy electrode 152 and the common electrode 141. An electrode gap G is formed between the electrode 131 and the electrode 132. In some embodiments, the distance between the center point of the electrode gap G and the center point of the first gap GD1 is greater than the distance between the center point of the electrode gap G and the center point of the second gap GD2. By this structure, the bar 121 and the bar 122 are parallel to each other, but not parallel to the axis D1. The formed transducers IDT1, IDT2, IDT3, and IDT4 can be shown as the dotted lines in FIG. 5. The number of transducers under this structure can be a positive even integer. The effective transducer area formed by this architecture is shown as the dotted lines in FIG. 5, which can effectively filter and reduce the convex wave effect in the frequency response. In one embodiment, the electrode gap G may not necessarily to be a right angle, but may also be an acute angle. For example, the edge of the electrode 131 close to the electrode 132 and the edge of the electrode 132 close to the electrode 131 do not contact each other, and the two edges are not parallel to the direction D2 The direction forms the electrode gap G, so the electrode gap G forms an acute angle.

The transducer shown in FIG. 5 may include a plurality of electrodes and a plurality of common electrodes. In one embodiment, a plurality of transducers such as the transducer IDT1 and the transducer IDT3 are aligned parallel to the bar 121 to form the transducer IDT11. Under the similar electrical structure, a plurality of transducers such as the transducer IDT2 and the transducer IDT14 aligned parallel to the bar 121 form the transducer IDT12, and the transducers IDT11 and IDT12 are coupled in series. The number of transducers IDT11 and IDT12 can be a positive integer, for example but not limited to 3, 4, 5 . . . , etc. The transducers are coupled in parallel with each other.

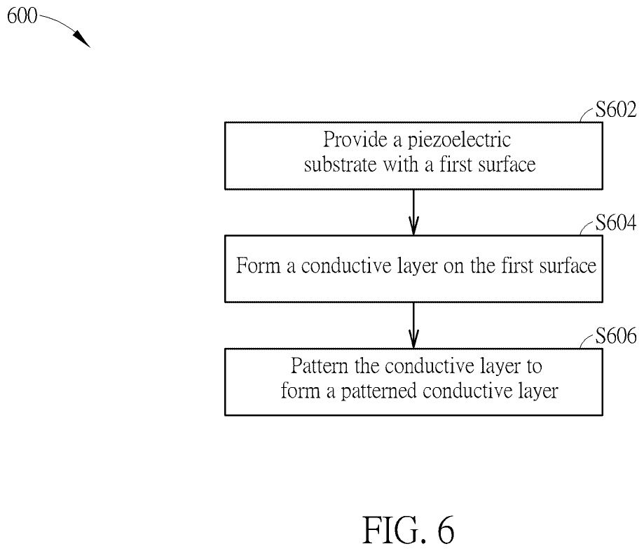

FIG. 6 is a flow chart of a manufacturing method 600 of an acoustic wave device according to an embodiment of the present invention. The manufacturing method includes the following steps:
Step S602: provide a piezoelectric substrate with a first surface;
Step S604: form a conductive layer on the first surface; and
Step S606: pattern the conductive layer to form a patterned conductive layer.

In step S602, a piezoelectric substrate is provided, and the piezoelectric substrate has a surface. In step S604, a conductive layer is formed on the surface. In step S606, the conductive layer is patterned to form a patterned conductive layer. The patterned conductive layer may include an electrode 131, an electrode 132, a floating common electrode 141, a dummy electrode 151, and a dummy electrode 152. The electrode 131 and the common electrode 141 form the transducer IDT1, and the electrode 132 and the common electrode 141 form the transducer IDT2. The transducer IDT1 and the transducer IDT2 are coupled in series through the common electrode 141. The dummy electrode 151 contacts the side e11 of the bar 121 and extends from the side e11 of the bar 121 along the axis D2. The dummy electrode 152 contacts the side e21 of the bar 122 and extends from the side e21 of the bar 122 along the axis D2. The dummy electrode 151, the common electrode 141 and the dummy electrode 152 are aligned along the axis D2. The distance between the first end e411 of the common electrode 141 and the side e11 of the bar 121 is the same as the distance between the second end e412 of the common electrode 141 and the side e21 of the bar 122. In one embodiment, the conductive layer is patterned to form a patterned conductive layer corresponding to FIGS. 1-5.

The present invention provides an acoustic wave device as a filter, in which two transducers coupled in series can reduce the clutter effect, and more even number of parallel transducers of the structure can be extended to further reduce the clutter effect.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An acoustic wave device, comprising:
a piezoelectric substrate having a first surface; and
a series-coupled transducer set comprising a first transducer and a second transducer coupled in series, and disposed on the first surface of the piezoelectric substrate, wherein:
the first transducer comprises a first electrode and a common electrode; and
the second transducer comprises a second electrode and the common electrode;
wherein the common electrode is floating, and the first transducer and the second transducer are coupled in series through the common electrode.

2. The acoustic wave device of claim 1, wherein:
a projection of the first electrode and the common electrode along a first axis has a first overlapped area; and
a projection of the second electrode and the common electrode along the first axis has a second overlapped area.

3. The acoustic wave device of claim 2, wherein along a second axis, a length of the first overlapped area and a length of the second overlapped area are the same.

4. The acoustic wave device of claim 1, wherein the series-coupled transducer set further comprises:
a first bar extended along a first axis and having a first side parallel to the first axis; and
a second bar extended along the first axis and having a second side parallel to the first axis.

5. The acoustic wave device of claim 4, wherein the common electrode has a first end and a second end, and a distance between the first end of the common electrode and the first side of the first bar and a distance between the second end of the common electrode and the second side of the second bar are the same.

6. The acoustic wave device of claim 4, wherein the series-coupled transducer set further comprises:
a first dummy electrode contacting the first side of the first bar and extended from the first side of the first bar along a second axis; and
a second dummy electrode contacting the second side of the second bar and extended from the second side of the second bar along the second axis;
wherein the first dummy electrode, the common electrode and the second dummy electrode are aligned along the second axis.

7. The acoustic wave device of claim 4, wherein the first electrode and the second electrode are aligned along a second axis.

8. The acoustic wave device of claim 4, wherein the first electrode and the second electrode have a gap along a second axis.

9. The acoustic wave device of claim 4, wherein:
the first electrode contacts the first side of the first bar and extends from the first side of the first bar along a second axis; and
the second electrode contacts the second side of the second bar and extends from the second side of the second bar along the second axis.

10. The acoustic wave device of claim 4, wherein the series-coupled transducer set further comprises another first electrode, another second electrode and another common electrode, and the another common electrode is floating;
wherein the another first electrode and the another common electrode form a third transducer, and the another second electrode and the another common electrode form a fourth transducer; and the third transducer and the fourth transducer are coupled in series through the another common electrode.

11. The acoustic wave device of claim 10, wherein:
the first bar has a third side parallel to the first axis;
the second bar has a fourth side parallel to the first axis;
the another common electrode has a first end and a second end; and
a distance between the first end of the another common electrode and the third side of the first bar and a distance between the second end of the another common electrode and the fourth side of the second bar are the same.

12. The acoustic wave device of claim 11, wherein:
a distance between the first end of the common electrode and the third side of the first bar is greater than a distance between the first end of the another common electrode and the first side of the first bar.

13. The acoustic wave device of claim 11, wherein:
an extension of the first side and an extension of the third side are not colinear.

14. The acoustic wave device of claim 11, wherein the series-coupled transducer set further comprises:
a third dummy electrode contacting the third side of the first bar and extended from the third side of the first bar along a second axis; and
a fourth dummy electrode contacting the fourth side of the second bar and extended from the fourth side of the second bar along the second axis;
wherein the third dummy electrode, the another common electrode and the fourth dummy electrode are aligned along the second axis;
wherein the first dummy electrode, the second dummy electrode, the third dummy electrode, and the fourth dummy electrode have the same length along the second axis.

15. The acoustic wave device of claim 11, wherein:
a distance between a center of the common electrode and the third side of the first bar is different from a distance between the center of the common electrode and the first side of the first bar.

16. The acoustic wave device of claim 15, wherein:
the first electrode and the second electrode have an electrode gap;
the first dummy electrode and the common electrode have a first gap; and
the second dummy electrode and the common electrode have a second gap;
wherein a distance between the electrode gap and the first gap is greater than a distance between the electrode gap and the second gap.

17. The acoustic wave device of claim 10, wherein number of transducers in the series-coupled transducer set is a positive even integer.

18. The acoustic wave device of claim 10, wherein the common electrode is not coupled to the another common electrode.

19. A method of manufacturing an acoustic wave device, comprising:
providing a piezoelectric substrate with a first surface;
forming a conductive layer on the first surface; and
patterning the conductive layer to form a patterned conductive layer, the patterned conductive layer comprising:
a first transducer, comprising a first electrode and a common electrode; and
a second transducer, comprising a second electrode and the common electrode;
wherein the common electrode is floating, and the first transducer and the second transducer are coupled in series through the common electrode.

20. The method of claim 19, wherein the patterned conductive layer further comprises:
a first bar extended along a first axis and having a first side parallel to the first axis; and
a second bar extended along the first axis and having a second side parallel to the first axis;
wherein the common electrode has a first end and a second end; and
a distance between the first end of the common electrode and the first side of the first bar is the same as a distance between the second end of the common electrode and the second side of the second bar.
